(19) United States
(12) Patent Application Publication
(10) Pub. No.: US 2013/0133193 A1
(43) Pub. Date: May 30, 2013

(54) SURFACE MOUNT TECHNOLOGY PROCESS FOR ADVANCED QUAD FLAT NO-LEAD PACKAGE PROCESS AND STENCIL USED THEREWITH

(71) Applicants: Chih-Tai Hsu, Hsinchu City (TW); Nan-Cheng Chen, Hsin-Chu City (TW); Chih-Ming Chiang, Zhudong Township (TW); Hung-Chang Hung, Taipei City (TW); Xin Zhong, Shenzhen City (CN)

(72) Inventors: Chih-Tai Hsu, Hsinchu City (TW); Nan-Cheng Chen, Hsin-Chu City (TW); Chih-Ming Chiang, Zhudong Township (TW); Hung-Chang Hung, Taipei City (TW); Xin Zhong, Shenzhen City (CN)

(73) Assignee: MEDIATEK SINGAPORE PTE. LTD., Singapore (SG)

(21) Appl. No.: 13/305,502

(22) Filed: Nov. 28, 2011

(51) Int. Cl. H05K 3/34; H05K 3/12

(52) U.S. Cl. 29/840; 29/739

(57) ABSTRACT

The invention provides a surface mount technology process for an advanced quad flat no-lead package process and a stencil used therewith. The surface mount technology process for an advanced quad flat no-lead package includes providing a printed circuit board. A stencil with first openings is mounted over the printed circuit board. A solder paste is printed passing the first openings to form first solder paste patterns. The stencil is taken off. A component placement process is performed to place the advanced quad flat no-lead package comprising a die pad on the printed circuit board, wherein the first solder paste patterns contact a lower surface of the die pad, and an area ratio of the first openings to the lower surface of the die pad is between 1:2 and 1:10. A reflow process is performed to melt the first solder paste patterns to surround a sidewall of the die pad.

### BACKGROUND OF THE INVENTION

1. Field of the Invention

The present invention relates to a surface mount technology process for an advanced quad flat no-lead package process and a stencil used therewith, and in particular, to a solder joint design for a die pad of an advanced quad flat no-lead package.

2. Description of the Related Art

An advanced quad flat no-lead (aQFN) package is a leadless, multi-row and fine pitch lead frame package with advantages of having a low profile, small footprint, light weight and free-form I/O design, thereby having enhanced thermal and electrical performance. The aQFN package can be used as a high-volume cost-sensitive consumer application in, for example, telecommunication products, portable products, consumer products and medium lead count packages. Also, the aQFN package has a significant cost benefit be replacing Au wire with Cu wire. Therefore, the aQFN package can increase cost competitiveness with low wire costs.

However, the process reliability of surface mounting of the aQFN package to a printed circuit board (PCB) suffers from the stress of solder joints between the die pad/leads of the aQFN package and the PCB, leading to a solder joint cracking problem.

Thus, a novel aQFN package without the solder joint cracking problem is desirable.

### BRIEF SUMMARY OF INVENTION

A surface mount technology process for an advanced quad flat no-lead package process and a stencil used therewith is provided. An exemplary embodiment of a surface mount technology process for an advanced quad flat no-lead package, comprises providing a printed circuit board. A stencil with first openings is mounted over a top surface of the printed circuit board. A solder paste is printed passing the first openings to form first solder paste patterns on the top surface of the printed circuit board. Next, the stencil is taken off Next, a component placement process is performed to place the advanced quad flat no-lead package on the top surface of the printed circuit board, the advanced quad flat no-lead package comprising a die pad having an upper surface and a lower surface and leads surrounding the die pad, wherein the first solder paste patterns contact the lower surface of the die pad, and an area ratio of the first openings to the lower surface of the die pad is between 1:2 and 1:10. Next, a reflow process is performed to melt the first solder paste patterns into a first liquefied solder paste, wherein a portion of the first liquefied solder paste surrounds a sidewall of the die pad.

An exemplary embodiment of a stencil used in a surface mount technology process for an advanced quad flat no-lead package, comprises a steel plate having a central portion and a periphery portion surrounding the central portion. First openings are formed through the steel plate, within the central portion, wherein positions of the first openings correspond to a position of a die pad of the advanced quad flat no-lead package, and an area ratio of the first openings to a surface of the die pad, which contacts to a printed circuit board, is between 1:5 and 2:5.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIG. 1 shows a side view of one exemplary embodiment of an advanced quad flat no-lead package of the invention.

FIG. 2 shows a bottom view of one exemplary embodiment of an advanced quad flat no-lead package of the invention.

FIGS. 3-7 show one exemplary embodiment of a surface mount technology process for an advanced quad flat no-lead package of the invention.

FIG. 8 shows a top view of one exemplary embodiment of a stencil used in a surface mount technology process for an advanced quad flat no-lead package of the invention.

FIGS. 9a-9d show various exemplary embodiments of a design of first opening of a stencil of the invention.

### DETAILED DESCRIPTION OF INVENTION

The following description is a mode for carrying out the invention. This description is made for the purpose of illustrating the general principles of the invention and should not be taken in a limiting sense. The scope of the invention is best determined by reference to the appended claims. Wherever possible, the same reference numbers are used in the drawings and the descriptions to refer the same or like parts.

The present invention will be described with respect to particular embodiments and with reference to certain drawings, but the invention is not limited thereto and is only limited by the claims. The drawings described are only schematic and are non-limiting. In the drawings, the size of some of the elements may be exaggerated and not drawn to scale for illustrative purposes. The dimensions and the relative dimensions do not correspond to actual dimensions to practice of the invention.

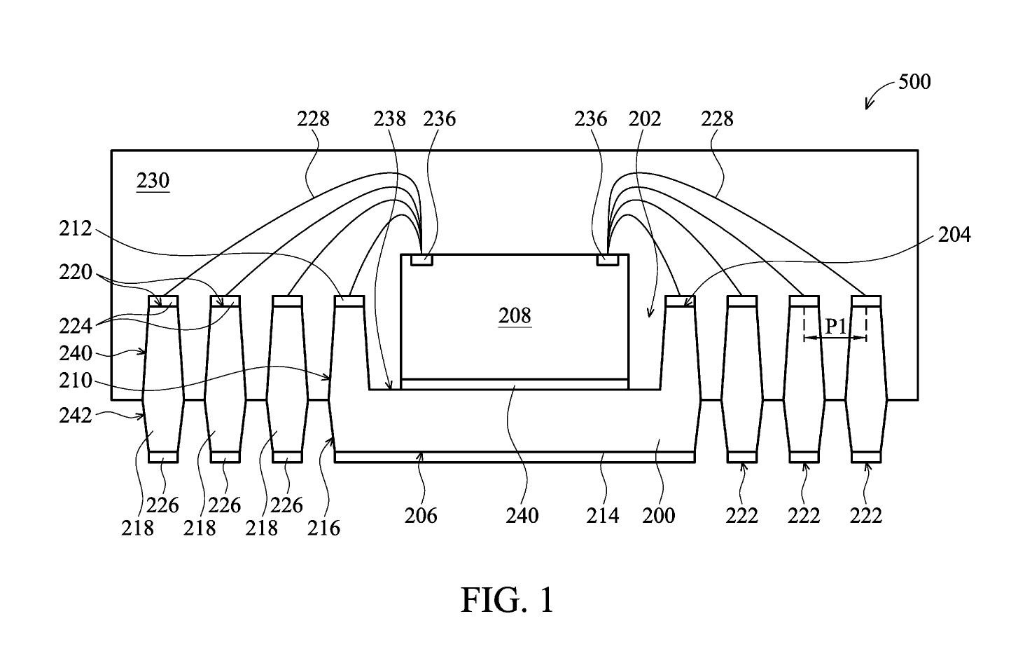

FIG. 1 shows a side view of one exemplary embodiment of an advanced quad flat no-lead package 500 of the invention. As shown in FIG. 1, the advanced quad flat no-lead (aQFN) package 500 comprises a die pad 200 in a central portion of the aQFN package 500, having an upper surface 204 and a lower surface 206. A cavity 202 is recessed from the upper surface 204 for a die 208 to be disposed therein. The die 208 is attached to a bottom surface 238 of the cavity 202 by an adhesive layer 240. The upper surface 204 and the lower surface 206 are respectively plated by metal layers 212 and 214. The aQFN package 500 comprises an upper side surface 210 and a lower side surface 216 respectively adjacent the upper surface 204 and the lower surface 206. It is noted that the upper side surface 210 and the lower side surface 216 of the die pad 200 are tilted to the upper surface 204 and the lower surface 206, respectively. The aQFN package 500 further comprises individual leads 218 surrounding the die pad 200. In one embodiment, the leads 218 are arranged in an array with a pitch P1. Each of the leads 218 has an upper surface 220 and a lower surface 222, and the upper surface 220 and the lower surface 222 are respectively plated by metal layers 224 and 226. It is noted that an upper side surface 240 and a lower side surface 242 of each of the leads 218 are tilted to the upper surface 220 and the lower surface 222, respectively. The die 208 has bonding pads 236 disposed thereon for input/output (I/O) connections. The bonding wires 224 are electrically connected between the metal layers 212 on the die pad 200, the metal layers 224 on the leads 218 and the bonding pads 236. The aQFN package 500 further comprises a mold cap 230 covering upper portions of the die pad 200 and the leads 218, the die 208 and the bonding wires 224.

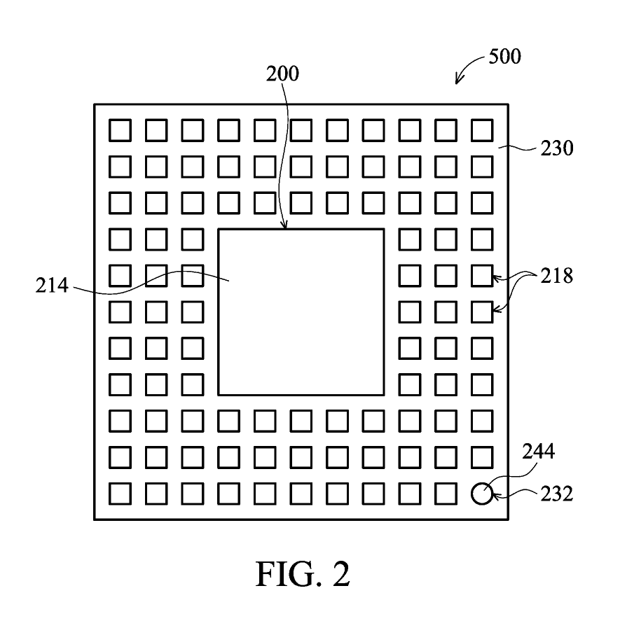

FIG. 2 shows a bottom view of one exemplary embodiment of an advanced quad flat no-lead package 500 of the invention. The lower surface 206 (as shown in FIG. 1), which is covered by the metal layer 214 as shown in FIG. 2, of the die pad 200 has an area which is much larger than the lower surface 222 (as shown in FIG. 1), which is covered by the metal layer 226 as shown in FIG. 2, of each of the leads 218 of the aQFN package 500. In one embodiment, the die pad 200 may serve as a thermal pad or a ground pad for the die 208. Additionally, the aQFN package 500 further comprises an alignment mark 232 for alignment purposes. Also, the alignment mark 232 has a metal layer 244 coated on a bottom surface thereof.

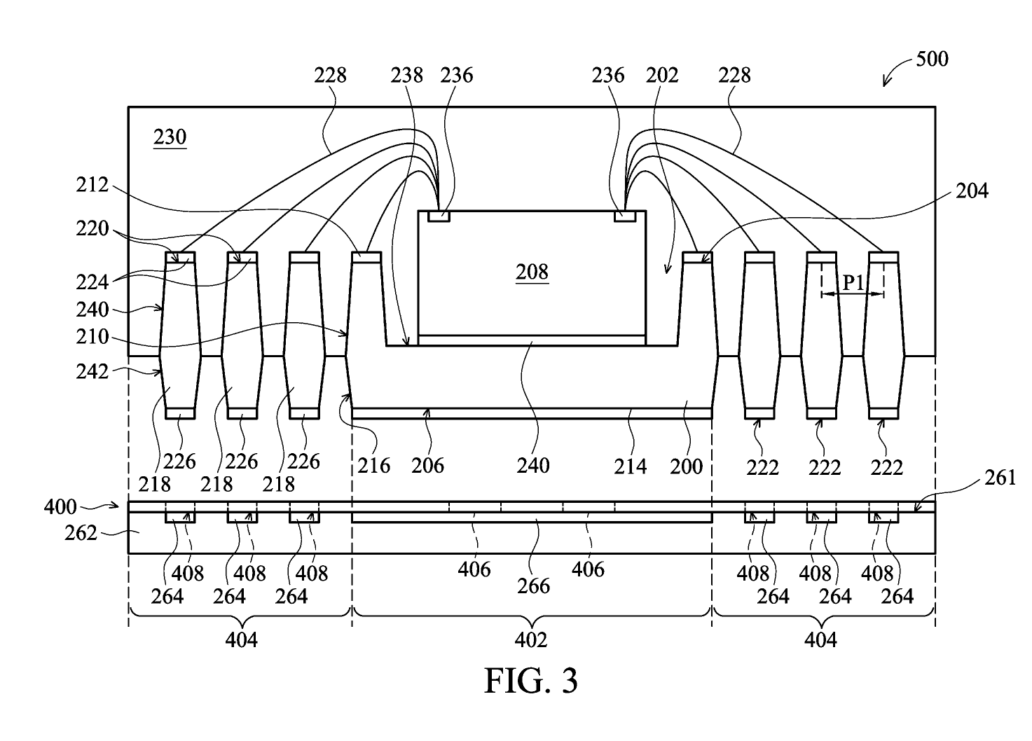

FIGS. 3-6 show one exemplary embodiment of a surface mount technology process for an advanced quad flat no-lead package 500 of the invention. As shown in FIG. 3, firstly, a printed circuit board 262 is provided. In one embodiment, the printed circuit board (PCB) 262 may comprise a thermal/ground pad 266 and several individual pads 264 (for example, signal pads or power pads). The aQFN package 500 is also shown in FIG. 3 to illustrate a relationship between positions of the leads 218 of the aQFN package 500 and the individual pads 264 of the PCB 262, and a relationship between positions of the die pad 200 of the aQFN package 500 and the thermal/ground pad 266 of the PCB 262. As shown in FIG. 3, positions of the individual pads 264 of the PCB 262 are respectively corresponded to that of the leads 218 of the aQFN package 500, and a position of the die pad 200 of the aQFN package 500 is corresponded to that of the thermal/ground pad 266 of the PCB 262.

Next, a stencil 400 with first openings 406 and second openings 408 is mounted over a top surface 261 of the PCB 262. The stencil 400 is used for formations of solder paste patterns respectively on the thermal/ground pad 266 and the individual pads 264 of the PCB 262 during the subsequence solder printing process. Therefore, as shown in FIG. 3, the first openings 406 are substantially aligned to the thermal/ground pad 266 of the PCB 262, and the second openings 408 are respectively aligned to the individual pads 264 of the PCB 262.

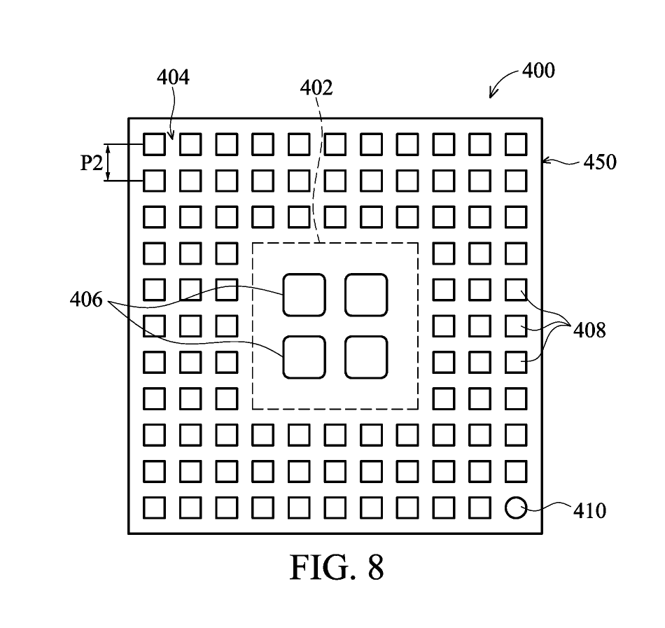

FIG. 8 shows a top view of one exemplary embodiment of a stencil 400 used for a surface mount technology process for an advanced quad flat no-lead package of the invention. As shown in FIGS. 3 and 8, the stencil 400 comprises a steel plate 450 having a central portion 402 and a periphery portion 404 surrounding the central portion. In one embodiment, the central portion 402 corresponds to an occupied position of the thermal/ground pad 266 of the PCB 262, and the periphery portion 404 corresponds to an occupied position of the individual pads 264 of the PCB 262. As shown in FIG. 8, the stencil 400 comprises first openings 406 which are formed through the steel plate 450, within the central portion 402. The first openings 406 are isolated from each other. Also, positions of the first openings 406 are designed substantially corresponding to the position of the die pad 200 of the aQFN package 500 (as shown in FIG. 1). In one embodiment, a total area of the first openings 406 is designed the same to that of the thermal/ground pad 266 of the PCB 262, but smaller than that of the die pad 200 of the aQFN package 500. In one embodiment, an area ratio of the first openings 406 to a lower surface 206 of the die pad 200 (as shown in FIG. 1) may be between 1:2 and 1:10. The stencil 400 further comprises individual second openings 408 formed through the steel plate 450, within the periphery portion 404. In one embodiment, the second openings 408 are arranged in an array with a pitch P2. Also, positions of the second openings 408 are designed corresponding to those of the leads 218 of the aQFN package 500 (as shown in FIG. 1), respectively. Therefore, the second openings have a pitch P2 which is the same as that of the pitch P1 of the leads 218. In one embodiment, each of the second openings 408 has the substantially same shape to the individual pads 264 of the PCB 262 and the lower surface 222 of each of the leads 218 of the aQFN package 500. In one embodiment, an area ratio of each of the second openings 408 to the individual pads 264 of the PCB 262/the lower surface 222 of each of the leads 218 of the aQFN package 500 is around 1:1. Alternatively, an area of each of the second openings 408 may be designed smaller than an area of the individual pads 264 of the PCB 262/the lower surface 222 of each of the leads 218 of the aQFN package 500.

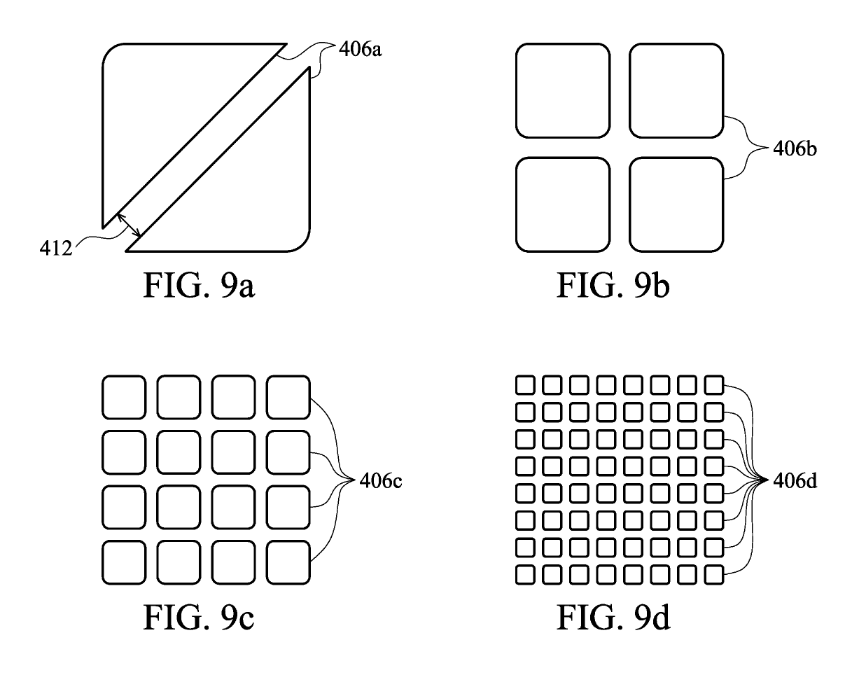

FIGS. 9a-9d shows various exemplary embodiments of a design of first openings of a stencil 400 (as shown in FIG. 8) of the invention. In one embodiment, a number of the first openings 406 may be larger than two. As shown in FIG. 9a, in one embodiment, two first openings 406a may be triangular shape, and bases 412 of the two triangular first openings 406a may face to each other. In one embodiment, the first openings 406 having a number more than two may be arranged in an array. The first openings 406b, 406c and 406d as shown in FIGS. 9b to 9d may be arranged in 2×2, 4×4 and 8×8 arrays, respectively. It is noted that the number and the shape of the first openings 406 may be according to design, but is not limited to the disclosed embodiments.

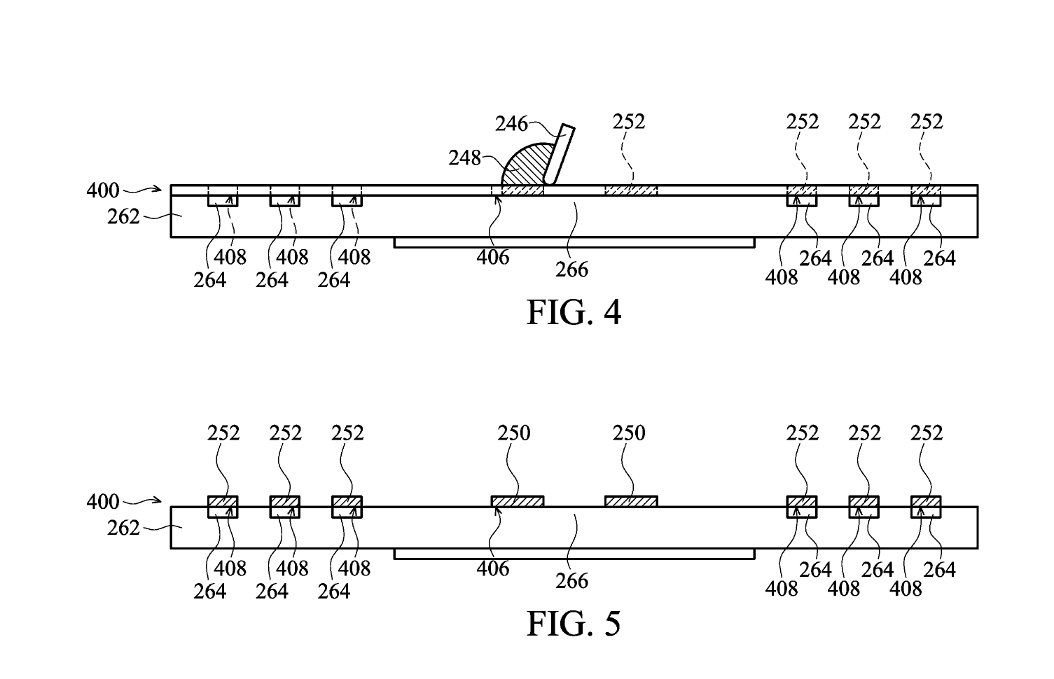

Next, as shown in FIG. 4, a solder printing process is performed to print a solder paste 248 passing the first openings 406 to form first solder paste patterns 250 on the thermal/ground pad 266 of the PCB 262 using a squeeze 246. Also, the solder paste 248 is printed passing the second openings 408 to form second solder paste patterns 252 respectively on the individual pads 264 of the PCB 262 during the solder printing process.

Next, as shown in FIG. 5, after performing the solder printing process, the stencil 400 as shown in FIG. 4 is taken off. As shown in FIG. 5, the first solder paste patterns 250 are formed overlapping with the thermal/ground pad 266 of the PCB 262. Further, boundaries of the second solder paste patterns 252 are respectively aligned to boundaries of the individual pads 264 of the PCB 262.

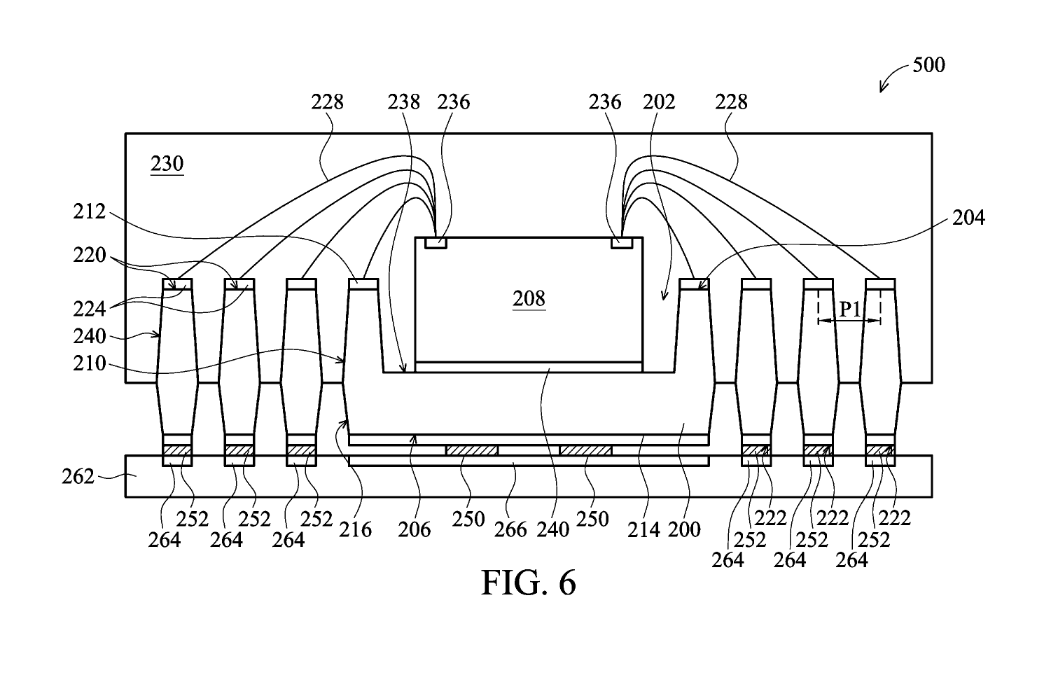

Next, as shown in FIG. 6, a component placement process is performed to place the aQFN package 500 on the PCB 262. After performing the component placement process, the first solder paste patterns 250 contact the lower surface 206 of the die pad 200 of the aQFN package 500, and the second solder paste patterns 252 are respectively aligned contact the lower surface 222 of each of the leads 218 of the aQFN package 500. In one embodiment, the first solder paste patterns 250 are designed to not fully cover the lower surface 206 of the die pad 200 by controlling the area ratio of the first openings 406 of the stencil 400 to a lower surface 206 of the die pad 200 of the aQFN package 500. Therefore, the amount of the solder paste contact the lower surface 206 of the die pad 200 of the aQFN package 500 is reduced to be less than that of the conventional solder paste which fully covers a lower surface of a die pad.

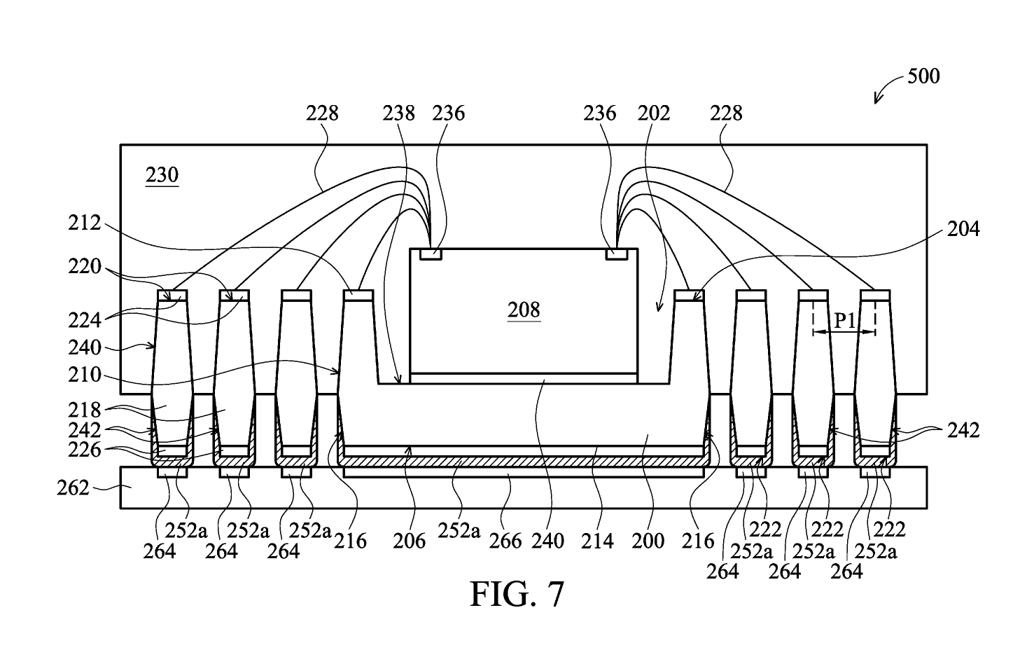

Next, as shown in FIG. 7, a reflow process is performed to melt the isolated first solder paste patterns 250 into a liquefied first solder paste 250a covering the lower surface 206 of the die pad 200. Also, the second solder paste patterns 252 are melted into the liquefied second solder paste 252a respectively covering the lower surfaces 222 of the leads 218 during the reflow process. It is noted that the liquefied first solder paste 250a covering the lower surface 206 of the die pad 200, which has an area much larger than that of the lower surface 222 of each of the leads 218, has a reduced amount, thus, the resistance of the liquefied first solder paste 250a to the die pad 200 of the aQFN package 500 thereon is less than the conventional solder paste fully covering the lower surface of the die pad. Therefore, the liquefied first solder paste 250a is pressed and squeezed upwardly to cover the sidewall 216 of the die pad 200 due to the weight of the aQFN package 500 during the reflow process. After performing the reflow process, a portion of the liquefied first solder paste 250a surrounds the sidewall 216 of the die pad 200, and a remaining portion of the first liquefied solder paste 250a is between the die pad 200 the thermal/ground pad 266 of the PCB 262. Also, a portion of each of the liquefied second solder pastes 252a may surround the sidewall 216 of each of the leads 218, and a remaining portion of each of the second solder pastes 252a is between the lead 218 and the pad 264 of the PCB 262 after performing the reflow process.

Referring to in FIG. 7 again, a cooling process is performed to solidify the liquefied first solder paste 250a into a first solder joint 250a, which serves as an electrical connection between the die pad 200 of the aQFN package 500 and the thermal/ground pad 266 of the printed circuit board 262. Also, the liquefied second solder pastes 252a are solidified into second solder joints 252a, which serve as electrical connections between the leads 218 of the aQFN package 500 and the pads 266 of the printed circuit board 262 after performing the cooling process. As shown in FIG. 7, in one embodiment, the first solder joint 250a has a fillet portion, which surrounds the sidewall 216 of the die pad 200, to clamp the die pad 200. Therefore, the mechanical strength between the die pad 200 of the aQFN package 500 and the thermal/ground pad 266 of the printed circuit board 262 is improved. Alternatively, each of the second solder joints 252a may have a fillet portion, which surrounds the sidewall 216 of each of the leads 218 to clamp the each of the leads 218.

One embodiment of the invention provides a surface mount technology (SMT) process for an advanced quad flat no-lead (aQFN) package and a stencil used therewith. In one embodiment of a solder printing process of the SMT process, the solder paste patterns connecting to the die pad of the aQFN package are designed to not fully cover the lower surface of the die pad by controlling the area ratio of the openings of the stencil, which are designed corresponding to the die pad, to the lower surface of the die pad. Therefore, the amount of the solder paste connecting to the lower surface of the die pad is reduced to be less than that of the conventional solder paste fully covering a lower surface of a die pad. Further, in one embodiment of a reflow process of the SMT process, the liquefied solder paste on the lower surface of the die pad has a reduced amount. The resistance of the liquefied solder paste to the die pad thereon is less than the conventional solder paste fully covering the lower surface of the die pad of the aQFN package. Therefore, the liquefied solder paste is pressed and squeezed upwardly to cover a sidewall of the die pad due to the weight of the aQFN package. After solidifying the liquefied solder paste in the solder joint by performing a cooling process, the solder joint has a fillet portion clamping the die pad. Therefore, the mechanical strength between the die pad 200 of the aQFN package 500 and the thermal/ground pad 266 of the printed circuit board 262 is improved.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A surface mount technology process for an advanced quad flat no-lead package, comprising:
providing a printed circuit board;
mounting a stencil with first openings over a top surface of the printed circuit board;
printing a solder paste passing the first openings to form first solder paste patterns on the top surface of the printed circuit board;
taking off the stencil;
performing a component placement process to place the advanced quad flat no-lead package on the top surface of the printed circuit board, the advanced quad flat no-lead package comprising:
a die pad having an upper surface and a lower surface; and
leads surrounding the die pad,
wherein the first solder paste patterns contact the lower surface of the die pad, and an area ratio of the first openings to the lower surface of the die pad is between 1:2 and 1:10; and
performing a reflow process to melt the first solder paste patterns into a first liquefied solder paste, wherein a portion of the first liquefied solder paste surrounds a sidewall of the die pad.

2. The surface mount technology process for an advanced quad flat no-lead package as claimed in claim 1, further comprising cooling the first liquefied solder paste so that it forms a first solder joint.

3. The surface mount technology process for an advanced quad flat no-lead package as claimed in claim 1, wherein the stencil further comprises second openings isolated from the first openings.

4. The surface mount technology process for an advanced quad flat no-lead package as claimed in claim 3, further comprising printing the solder paste passing the second openings to form second solder paste patterns respectively on the top surface of the printed circuit board during forming the first solder paste patterns on the lower surface of the die pad.

5. The surface mount technology process for an advanced quad flat no-lead package as claimed in claim 5, wherein the second openings respectively contact the lower surfaces of the leads after performing the component placement process.

6. The surface mount technology process for an advanced quad flat no-lead package as claimed in claim 1, wherein the first solder paste patterns are within a boundary of the lower surface of the die pad after performing the component placement process.

7. The surface mount technology process for an advanced quad flat no-lead package as claimed in claim 1, wherein the first openings are isolated from each other.

8. The surface mount technology process for an advanced quad flat no-lead package as claimed in claim 1, wherein the first openings are arranged in an array.

9. The surface mount technology process for an advanced quad flat no-lead package as claimed in claim 1, wherein a remaining portion of the first liquefied solder paste is between the die pad and the printed circuit board.

10. The surface mount technology process for an advanced quad flat no-lead package as claimed in claim 1, wherein the sidewall of the die pad is adjacent the lower surface of the die pad.

11. The surface mount technology process for an advanced quad flat no-lead package as claimed in claim 5, further comprising melting the second solder paste patterns into second liquefied solder pastes, wherein a portion of each of the second liquefied solder pastes surrounds a sidewall of each of the leads when the reflow process is being performed.

12. A stencil used in a surface mount technology process for an advanced quad flat no-lead package, comprising:
a steel plate having a central portion and a periphery portion surrounding the central portion; and
first openings formed through the steel plate, within the central portion, wherein positions of the first openings correspond to a position of a die pad of the advanced quad flat no-lead package, and an area ratio of the first openings to a surface of the die pad, which contacts to a printed circuit board, is between 1:2 and 1:10.

13. The stencil used in a surface mount technology process for an advanced quad flat no-lead package as claimed in claim 12, further comprising second openings formed through the steel plate, within the periphery portion, wherein positions of the second openings correspond to the leads of the advanced quad flat no-lead package, respectively.

14. The stencil used in a surface mount technology process for an advanced quad flat no-lead package as claimed in claim 12, wherein the first openings are isolated from each other.

15. The stencil used in a surface mount technology process for an advanced quad flat no-lead package as claimed in claim 12, wherein the first openings are arranged in an array.

16. The stencil used in a surface mount technology process for an advanced quad flat no-lead package as claimed in claim 12, wherein the second openings have a pitch which is the same as the pitch of the leads.

17. The stencil used in a surface mount technology process for an advanced quad flat no-lead package as claimed in claim 12, wherein a boundary of the central portion corresponds to that of the die pad of the advanced quad flat no-lead package.
